(19) United States
(12) Patent Application Publication
(10) Pub. No.: US 2007/0285897 A1
(43) Pub. Date: Dec. 13, 2007

(54) Thermal module with heat pipe

(75) Inventors: Chi-Chun Huang, Taipei City (TW); Ching-Yu Hsu, Keelung City (TW)

Correspondence Address: BACON & THOMAS, PLLC, 625 SLATERS LANE, FOURTH FLOOR, ALEXANDRIA, VA, 22314, US

(73) Assignee: AMA Precision Inc., Taipei City (TW)

(21) Appl. No.: 11/709,125

(22) Filed: Feb. 22, 2007

(30) Foreign Application Priority Data
Jun. 8, 2006 (TW) 095120402

(51) Int. Cl. H05K 7/20

(52) U.S. Cl. 361/715

(57) ABSTRACT

A thermal module with heat pipe is disclosed to include a heat-dissipation plate, which has an accommodation groove that accommodates a heat pipe that is bonded to the accommodation groove with a bonding glue, and at least one retaining groove formed in the accommodation groove for retaining the bonding glue to prevent overflow of the bonding glue during its fluid state so as to improve the yield rate of the fabrication of the thermal module with heat pipe, avoid a further follow-up process, facilitate the quality control, save the cost, and keep a good looking of the finished product.

### BACKGROUND OF THE INVENTION

1. Field of the Invention

The present invention relates to a thermal module and more particularly, to a thermal module with heat pipe.

2. Description of Related Art

For a regular electronic product, such as a personal computer, a server, or a video player, usually installs at least one heat generating electronic device such as, a CPU, a graphic chip, or the like, therein. It is necessary to provide a thermal module in the electronic product to carry heat away from the internal heat generating electronic device, preventing accumulation of heat that may result in malfunctioning of the heat generating electronic device or cause damage to surrounding system chips. The thermal module may be formed of a heat-dissipation fins or a heat-dissipation fan or the like.

There is known a thermal module design that has a heat pipe bonded to a heat-dissipation plate. The bonding between the heat pipe and the heat-dissipation plate is achieved by means of the application of a heat-dissipation solder paste. This design of thermal module with heat pipe uses the heat-dissipation plate to absorb heat from the heat source, for enabling the absorbed heat energy to be transferred to the heat pipe by the heat-dissipation solder paste and then carried away by the heat pipe. The heat pipe has a fluid (for example, water) filled therein. The fluid is changed to steam when heated by the heat energy transferred from the heat-dissipation plate through the heat-dissipation solder paste, and the steam immediately flows to the remote end of the heat pipe to make a heat exchange. After the heat exchange, the steam is changed to the fluid state, which immediately flows back to the proximity end of the heat pipe for another heat exchange cycle. This procedure is repeated again and again, and therefore heat energy is continuously carried away from the heat source.

According to the aforesaid conventional technique, the heat pipe is directly mounted in a groove on the heat-dissipation plate and fixedly secured thereto by means of a heat-dissipation solder paste. This design has a surface contact between the heat pipe and the heat-dissipation plate, increasing the heat absorbing surface area of the heat pipe.

However, when bonding the heat pipe to the heat-dissipation plate with a heat-dissipation solder paste, the control of the flowing direction of the applied fluid state heat-dissipation solder paste is not easy because many factors such as the amount and purity of the tin solder applied, the manufacturing process employed, the machine tools used, or the positioning status of the heat-dissipation heat plate with the tin solder and the heat pipe in the soldering stove may affect the flowing direction of the fluid state tin solder (heat-dissipation solder paste).

Therefore, an overflow of the heat-dissipation solder paste may occur (the heat-dissipation solder paste may flow over the heat-dissipation plate and the heat pipe), resulting in a low yield rate of the fabrication and a bad looking of the finished thermal module with heat pipe. Further, when an overflow of the heat-dissipation solder paste occurred, a further follow-up procedure is necessary, thereby increasing the cost.

### SUMMARY OF THE INVENTION

The present invention has been accomplished under the circumstances in view. It is therefore the main object of the present invention to provide a thermal module with heat pipe that eliminates the drawback of the aforesaid conventional design.

According to the present invention, the thermal module with heat pipe is comprised of a heat-dissipation plate and a heat pipe.

The heat-dissipation plate has a top surface, a bottom surface, and an accommodation groove formed in the top surface of the heat-dissipation plate. The heat pipe is accommodated in the accommodation groove of the heat-dissipation plate by a bonding glue.

The main feature of the present invention is that the heat-dissipation plate further has at least one retaining groove formed in the accommodation groove.

After mounting of the heat pipe in the accommodation groove of the heat-dissipation plate, the bonding glue will flow in between the heat pipe and the heat-dissipation plate during its fluid state. However, it is not necessary to consider the flowing direction or overflow of the bonding glue. Because the accommodation groove of the heat-dissipation plate has at least one retaining groove in it that prevent overflow of the bonding glue, i.e., each retaining groove works as detaining means to retain excessive amount of the bonding glue when the bonding glue is forced outwards toward the two distal ends of the accommodation groove by the pressure of the heat pipe upon insertion of the heat pipe into the accommodation groove. Because the present invention prevents overflow of the bonding glue, the yield rate of the fabrication of the thermal module with heat pipe according to the present invention is high, and no further follow-up processing process is necessary after bonding of the heat pipe to the heat-dissipation plate, i.e., the present invention greatly improves the quality control and saves the cost. Further, because the present invention prevents overflow of the bonding glue, the finished thermal module with heat pipe has a nice outer appearance.

Further, the bonding glue can be a heat-dissipation solder paste, adhesive, or any suitable bonding agent capable of bonding the heat pipe to the heat-dissipation plate. When a heat-dissipation solder paste is used, the condition of the aforesaid “overflow” is called “overflow of tin solder”.

Further, the accommodation groove can be fitted the heat pipe in shape. For example, the accommodation groove can be a straight groove, and the heat-pipe can be a straight pipe fitting the straight accommodation groove. Alternatively, the accommodation groove can be a curved groove, and the heat-pipe can be a curved pipe fitting the curved accommodation groove.

Further, the number of the at least one retaining groove can be two. In this case, the two retaining grooves are formed near the two distal ends of the accommodation groove respectively. When the bonding glue is flowing toward the two distal ends of the accommodation groove, the two retaining grooves retain the bonding glue, preventing overflow.

In an alternate form of the present invention, the thermal module with heat pipe is comprised of a heat-dissipation heat plate and at least two heat pipes.

The heat-dissipation heat plate has a top surface, a bottom surface, and at least two accommodation grooves formed in the top surface. The at least two heat pipes are respectively accommodated in the at least two accommodation grooves of the heat-dissipation plate by a bonding glue.

Similarly, the heat-dissipation plate further has at least one retaining groove formed in at least one of the at least two accommodation grooves to retain the applied bonding glue, preventing overflow of the bonding glue.

Further, the number of the at least one retaining groove can be two, and the two retaining grooves are formed near the two distal ends of at least one of the at least two accommodation grooves respectively.

Further, the number of the at least one retaining groove can be two, and the two retaining grooves are formed in the at least two accommodation grooves respectively. In this design, the two retaining grooves of the at least two accommodation grooves are at the same side in the at least two accommodation grooves and are connected to one another.

Further, the number of the at least one retaining grooves can be four, and the four retaining grooves are respectively disposed in the at least two accommodation grooves near the two distal ends of the at least two accommodation grooves.

### BRIEF DESCRIPTION OF THE DRAWINGS

FIG. 1 is an exploded view of a thermal module with heat pipe in accordance with a first embodiment of the present invention.

FIG. 2 is a sectional assembly view of the thermal module with heat pipe in accordance with the first embodiment of the present invention.

FIG. 3 is perspective view of a thermal module with heat pipe in accordance with a second embodiment of the present invention.

FIG. 4 is an exploded view of a thermal module with heat pipe in accordance with a third embodiment of the present invention;

FIG. 5 is an exploded view of a thermal module with heat pipe in accordance with a fourth embodiment of the present invention.

FIG. 6 is a perspective view of a thermal module with heat pipe in accordance with a fifth embodiment of the present invention.

FIG. 7 is an exploded view of a thermal module with heat pipe in accordance with a sixth embodiment of the present invention.

FIG. 8 is an exploded view of a thermal module with heat pipe in accordance with a seventh embodiment of the present invention.

FIG. 9 is an exploded view of a thermal module with heat pipe in accordance with an eighth embodiment of the present invention.

FIG. 10 is an exploded view of a thermal module with heat pipe in accordance with a ninth embodiment of the present invention.

### DETAILED DESCRIPTION OF THE PREFERRED EMBODIMENT

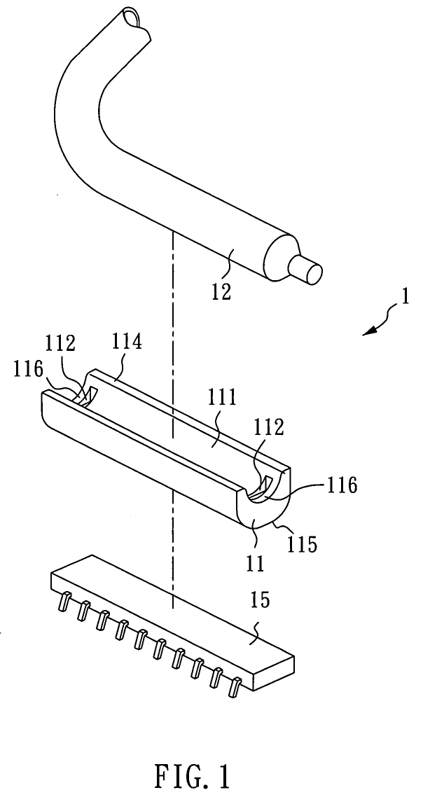

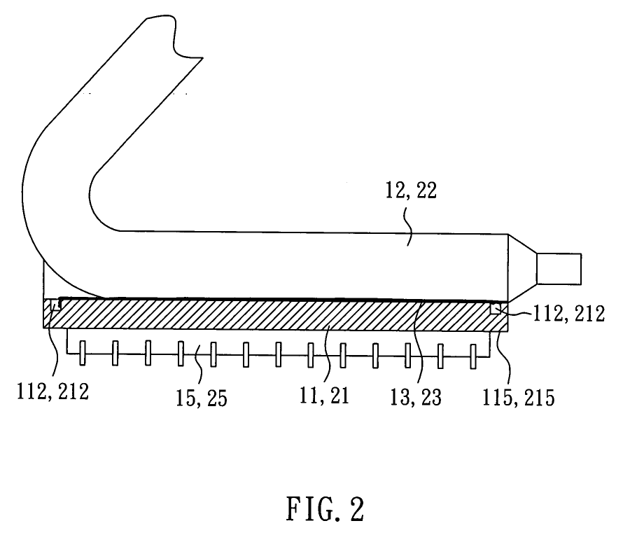

Referring to FIGS. 1 and 2, a thermal module with heat pipe in accordance with a first embodiment of the present invention is shown. The thermal module 1 includes a heat-dissipation plate 11, a bonding glue 13, and a heat pipe 12.

The heat-dissipation plate 11 has a top surface 114, a bottom surface 115 opposite to the top surface 114, an accommodation groove 111 formed in the top surface 114, and two transverse retaining grooves 112 formed in the accommodation groove 111 near the two distal ends of the accommodation groove 111. The heat pipe 11 is accommodated in the accommodation groove 111 by the bonding glue 13.

In this embodiment, the bottom surface 115 of the heat-dissipation plate 11 is attached to a heat generating electronic device 15. The heat generating electronic device 15 can be a CPU, a graphic chip, a network processing chip, a RAID chip, or the like. According to this embodiment, the heat generating electronic device 15 is a CPU. The heat-dissipation plate 11 and the heat pipe 12 according to this embodiment are made of copper for the advantage of high coefficient of heat transfer. Aluminum or any of a variety of other equivalent materials may be used as a substitute. Further, the bonding glue 13 can be obtained from any of a variety of adhesives capable of bonding the heat pipe 12 to the heat-dissipation plate 11. According to this embodiment, the bonding glue 13 is a heat-dissipation solder paste.

Further, the shape of the accommodation groove 111 of the heat-dissipation plate 11 fits the shape of the heat pipe 12, i.e., the accommodation groove 111 is a straight groove fitting the straight heat pipe 12. Further, the heat pipe 12 is a round pipe. The accommodation groove 111 has a semicircular cross section. When the heat pipe 12 is bonded to the accommodation groove 111 by the bonding glue 13 (heat-dissipation solder paste), the heat pipe 12 and the heat-dissipation plate 11 are matched perfectly, providing a surface contact and increasing the heat absorbing surface area of the heat pipe 12.

After bonding of the heat pipe 12 to the accommodation groove 111 of the heat-dissipation plate 11 by the bonding glue 13 (heat-dissipation solder paste), the desired thermal module is thus obtained. During application, the heat-dissipation plate 11 absorbs heat energy from the heat generating electronic device 15 and transfers absorbed heat energy to the heat pipe 12 for enabling the heat pipe 12 to carry heat energy away from the heat-dissipation plate 12. The heat dissipation work of the heat pipe 12 is of the known art, no further detailed description in this regard is necessary.

When accommodating the heat pipe 12 in the accommodation groove 111 of the heat-dissipation plate 11, the bonding glue 13 (heat-dissipation solder paste) is flowing in the accommodation groove 111 between the heat-dissipation plate 11 and the heat pipe 12 during its fluid state. Thereafter, the bonding glue 13 (heat-dissipation solder paste) is cooled down and hardened to affix the heat pipe 12 to the heat-dissipation plate 11.

According to the present invention, it is unnecessary to consider the flowing direction or overflow of the bonding glue 13 during the fluid state of the bonding glue 13. Because the accommodation groove 111 is a straight groove having a semicircular cross section and because the two transversely extending retaining grooves 112 are disposed near the two distal ends of the accommodation groove 111, the retaining grooves 112 prevent overflow of the bonding glue 13, i.e., the retaining grooves 112 work as detaining means to retain excessive amount of the bonding glue 13 when the bonding glue 13 is forced outwards toward the two distal ends of the accommodation groove 111 upon insertion of the heat pipe 12 into the accommodation groove 111. Because the invention prevents overflow of the bonding glue 13, the yield rate of the present invention is high, and no further follow-up processing process is necessary, i.e., the invention greatly improves the quality control and saves the cost. Further, because the invention prevents overflow of the bonding glue 13, the finished thermal module with heat pipe has a nice outer appearance.

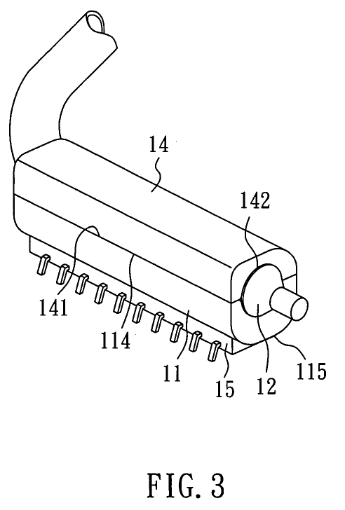

FIG. 3 illustrates a thermal module with heat pipe in accordance with a second embodiment of the present invention. This embodiment is substantially similar to the aforesaid first embodiment with the exception of the use of a top cover 14 that is covered on the heat-dissipation plate 11 over the heat pipe 12.

According to this embodiment, the top cover 14 has a bottom surface 141 abutted to the top surface 114 of the heat-dissipation plate 11, and an accommodation groove 142 formed in the bottom surface 141 and fitting the shape of the heat pipe 12 and accommodated the heat pipe 12.

According to this embodiment, the top cover 14 is made of copper. Further, the top cover 14 can be made having radiation fins to facilitate dissipation of heat. This second embodiment not only achieves the various effects of the aforesaid first embodiment but also enhances the heat dissipation efficiency.

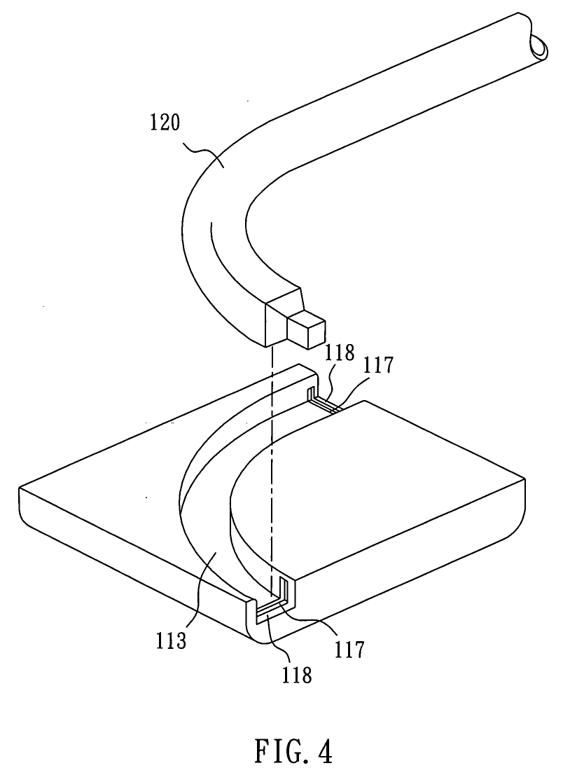

FIG. 4 is an exploded view of a thermal module with heat pipe in accordance with a third embodiment of the present invention. This embodiment is substantially similar to the aforesaid first embodiment with the exception that the accommodation groove 113 is curved, having two transverse retaining grooves 117 respectively disposed near the two distal ends 118 thereof; the heat pipe 120 is a curved pipe fitting the curved profile of the accommodation groove 113.

According to this third embodiment, the heat pipe 120 is a curved pipe. This embodiment achieves the various effects of the aforesaid first embodiment. Further, the heat pipe 120 is a rectangular pipe. The accommodation groove 113 has a rectangular cross section fitting the rectangular cross section of the heat pipe 120. This design relatively increases the heat absorbing area of the heat pipe 120. According to this third embodiment and the aforesaid first embodiment, the shape of the accommodation groove 113 is determined subject to the shape of the heat pipe 120.

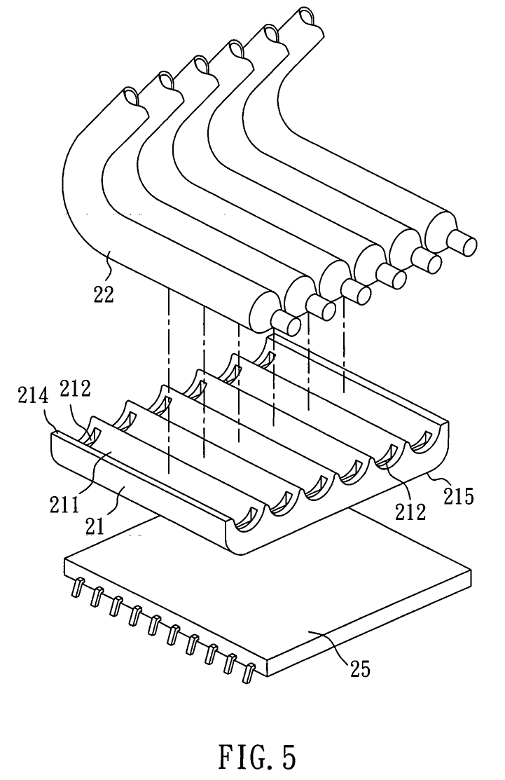

FIG. 5 is an exploded view of a thermal module with heat pipe in accordance with a fourth embodiment of the present invention. Please refer also to FIG. 2, the thermal module with heat pipe in accordance with this fourth embodiment is comprised of a heat-dissipation plate 21, a plurality of heat pipes 22, and a bonding glue 23. The heat-dissipation plate 21 has a top surface 214, a bottom surface 215, a plurality of accommodation grooves 211 formed in the top surface 214, and a plurality of transverse retaining grooves 212 respectively formed in the accommodation grooves 211 near the two distal ends of the associating accommodation grooves 211. The heat pipes 22 are respectively accommodated to the accommodation grooves 211 of the heat-dissipation plate 21 by the bonding glue 23. Further, the bottom surface 215 of the heat-dissipation plate 21 is attached to a heat generating electronic device 25, for example, a CPU.

Further, the shape of the accommodating grooves 211 fits the shape of the heat pipes 22. According to this embodiment, the accommodation grooves 211 are straight grooves; the heat pipes 22 are straight pipes respectively fitted into the accommodation grooves 211.

Similar to the aforesaid first embodiment, the retaining grooves 212 prevent overflow of the bonding glue 23, i.e., this embodiment facilitates the quality control and saves the cost, and the finished thermal module with heat pipe according to this embodiment has a nice outer appearance.

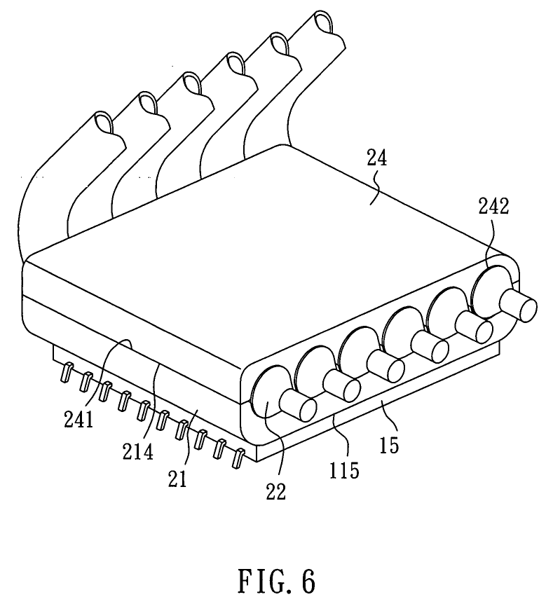

FIG. 6 is a perspective view of a thermal module with heat pipe in accordance with a fifth embodiment of the present invention. This embodiment is substantially similar to the aforesaid fourth embodiment with the exception of the use of a top cover 24 (as well as second embodiment), which has a bottom surface 241 abutted against the top surface 214 of the heat-dissipation plate 21, and a plurality of accommodation grooves 242 formed in the bottom surface 241 to accommodate the heat pipes 22.

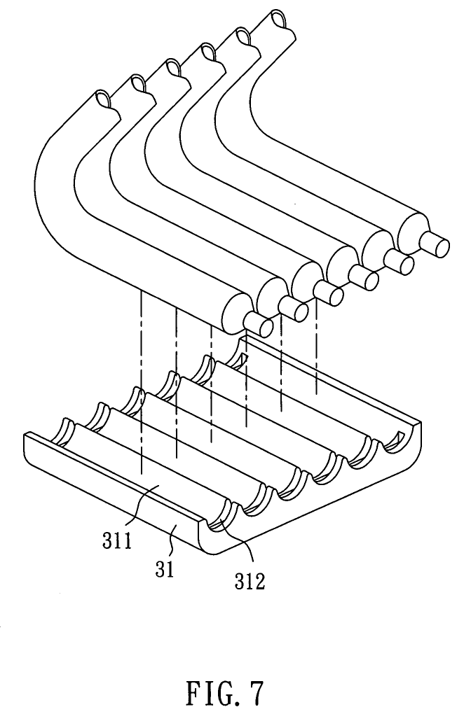

FIG. 7 is an exploded view of a thermal module with heat pipe in accordance with a sixth embodiment of the present invention. This embodiment is substantially similar to the aforesaid fourth embodiment with the exception that the transversely extending retaining grooves 312 in the accommodation grooves 311 at the same end are connected to one another in series. This embodiment achieves the same various effects of the aforesaid various embodiments.

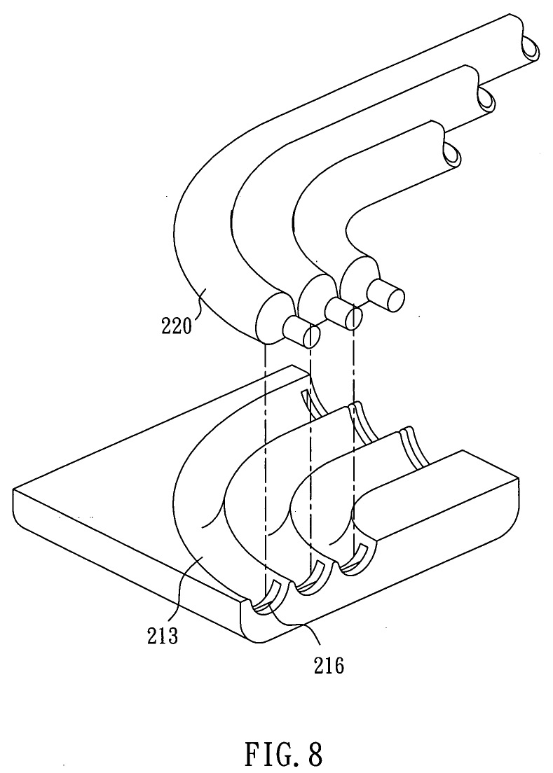

FIG. 8 is an exploded view of a thermal module with heat pipe in accordance with a seventh embodiment of the present invention. This embodiment is substantially similar to the aforesaid fourth embodiment with the exception that the accommodation grooves 213 of the thermal module with heat pipe of this seventh embodiment are curved grooves and the retaining grooves 216 in the accommodation grooves 213 are spaced apart. Further, the heat pipes 220 are curved pipes fitting the curved accommodation grooves 213. Therefore, this seventh embodiment achieves the same various effects of the aforesaid various different embodiments of the present invention.

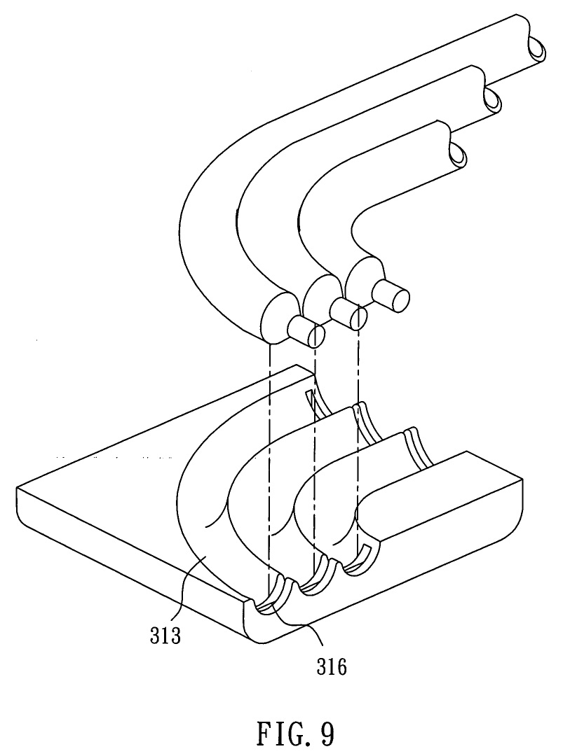

FIG. 9 is an exploded view of a thermal module with heat pipe in accordance with an eighth embodiment of the present invention. This embodiment is substantially similar to the aforesaid seventh embodiment with the exception that the retaining grooves 316 in the accommodation grooves 313 at the same side are connected to one another in series.

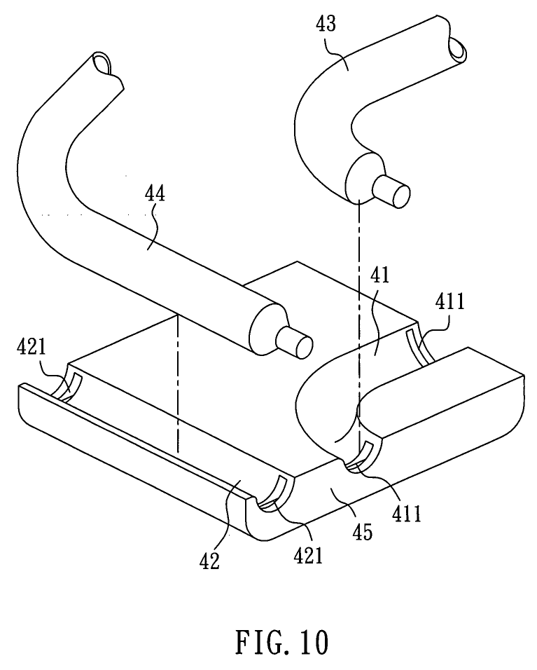

FIG. 10 is an exploded view of a thermal module with heat pipe in accordance with a ninth embodiment of the present invention. According to this embodiment, the accommodation grooves 41 and 42 of the heat-dissipation plate 45 have different shapes corresponding to different heat pipes 43 and 44, i.e., the heat-dissipation plate 45 has a curved accommodation groove 41 and a straight accommodation groove 42, and the heat pipes 43 and 44 have different shapes that fit the curved accommodation groove 41 and the straight accommodation groove 42 respectively. Further, each accommodation groove 41 or 42 has two transversely extending retaining grooves 411 or 421 disposed near the two distal ends to prevent overflow of the bonding glue (not shown). This embodiment achieves the same various effects of the aforesaid various different embodiments of the present invention.

As stated in the aforesaid various embodiments of the present invention, the retaining grooves are designed subject to actual requirements, for example, the number of the retaining grooves can be two or more than two that are formed in the accommodation groove or at least one of the accommodation grooves near the two distal ends. The retaining grooves in the accommodation grooves at the same side can be designed kept apart, or connected to one another in series. Alternatively, the number of the retaining grooves can be four, and the four retaining grooves are respectively disposed in two accommodation grooves near two distal ends. In general, the number and arrangement of the retaining grooves may be variously embodied to fit the accommodation grooves subject to different requirements.

Further, the retaining grooves can be made having any of a variety of cross-sectional shapes. For example, the retaining grooves can be made having a rectangular, triangular, semicircular, or trapezoidal shape.

Although the present invention has been explained in relation to its preferred embodiment, it is to be understood that many other possible modifications and variations can be made without departing from the spirit and scope of the invention as hereinafter claimed.

What is claimed is:

1. A thermal module with heat pipe comprising:
a heat-dissipation plate, having a top surface, a bottom surface, and an accommodation groove formed in the top surface; and
a heat pipe accommodated in the accommodation groove by a bonding glue;
wherein the heat-dissipation plate further has at least one retaining groove formed in the accommodation groove.

2. The thermal module with heat pipe as claimed in claim 1, wherein the bonding glue is a heat-dissipation solder paste.

3. The thermal module with heat pipe as claimed in claim 1, wherein the accommodation groove fits the heat pipe in shape.

4. The thermal module with heat pipe as claimed in claim 1, wherein the number of the at least one retaining groove is two, and the two retaining grooves are formed near two distal ends of the accommodation groove respectively.

5. The thermal module with heat pipe as claimed in claim 1, further comprising a top cover covered on the heat-dissipation plate.

6. The thermal module with heat pipe as claimed in claim 5, wherein the top cover has a bottom surface abutted against the top surface of the heat-dissipation plate, and an accommodation groove formed in the bottom surface of the top cover and adapted to accommodate the heat pipe, the accommodation groove of the top cover fits the heat pipe in shape.

7. The thermal module with heat pipe as claimed in claim 1, wherein the bottom surface of the heat-dissipation plate is attached to a heat generating electronic device.

8. A thermal module with heat pipe comprising:
a heat-dissipation plate, having a top surface, a bottom surface, and at least two accommodation grooves formed in the top surface; and
at least two heat pipes respectively accommodated in the at least two accommodation grooves of the heat-dissipation plate by a bonding glue;
wherein the heat-dissipation plate further has at least one retaining groove formed in at least one of the at least two accommodation grooves.

9. The thermal module with heat pipe as claimed in claim 8, wherein the bonding glue is a heat-dissipation solder paste.

10. The thermal module with heat pipe as claimed in claim 8, wherein the at least two accommodation grooves fit the at least two heat pipes in shape respectively.

11. The thermal module with heat pipe as claimed in claim 8, wherein the number of the at least one retaining groove is two, and the two retaining grooves are formed near two distal ends of at least one of the at least two accommodation grooves respectively.

12. The thermal module with heat pipe as claimed in claim 8, wherein the number of the at least one retaining groove is two, and the two retaining grooves are formed in the at least two accommodation grooves respectively.

13. The thermal module with heat pipe as claimed in claim 12, wherein the two retaining grooves of the at least two accommodation grooves are at the same side in the at least two accommodation grooves and are connected to one another.

14. The thermal module with heat pipe as claimed in claim 8, wherein the number of the at least one retaining grooves is four, and the four retaining grooves are respectively disposed in the at least two accommodation grooves near two distal ends of the at least two accommodation grooves.

15. The thermal module with heat pipe as claimed in claim 8, further comprising a top cover covered on the heat-dissipation plate.

16. The thermal module with heat pipe as claimed in claim 15, wherein the top cover has a bottom surface abutted against the top surface of the heat-dissipation plate, and at least two accommodation grooves formed in the bottom surface of the top cover and adapted to accommodate the at least two heat pipes, the at least two accommodation grooves of the top cover fit the at least two heat pipes in shape respectively.

17. The thermal module with heat pipe as claimed in claim 8, wherein the bottom surface of the heat-dissipation plate is attached to a heat generating electronic device.
